(19) United States
(12) Patent Application Publication
(10) Pub. No.: US 2014/0315331 A1
(43) Pub. Date: Oct. 23, 2014

(54) Screening of Surface Passivation Processes for Germanium Channels

(71) Applicant: Intermolecular, Inc., San Jose, CA (US)

(72) Inventors: Sandip Niyogi, San Jose, CA (US); Shuogang Huang, San Jose, CA (US); Chi-I Lang, Cupertino, CA (US)

(73) Assignee: Intermolecular, Inc., San Jose, CA (US)

(21) Appl. No.: 14/205,078

(22) Filed: Mar. 11, 2014

Related U.S. Application Data
(60) Provisional application No. 61/779,094, filed on Mar. 13, 2013.

(51) Int. Cl. H01L 21/66; H01L 21/306

(52) U.S. Cl. CPC H01L 22/26; H01L 21/30604
USPC 438/8; 438/745

(57) ABSTRACT

Candidate wet processes for native oxide removal from, and passivation of, germanium surfaces can be screened by high-productivity combinatorial variation of different process parameters on different site-isolated regions of a single substrate. Variable process parameters include the choice of hydrohalic acid used to remove the native oxide, the concentration of the acid in the solution, the exposure time, and the use of an optional sulfur passivation step. Measurements to compare the results of the process variations include attenuated total reflectance Fourier transform infrared spectroscopy (ATR-FTIR), contact angle, atomic force microscopy (AFM), scanning electron microscopy (SEM), and X-ray fluorescence (XRF). A sample screening experiment indicated somewhat less native oxide regrowth using HCl or HBr without sulfur passivation, compared to using HF with sulfur passivation.

### CROSS-REFERENCE TO RELATED APPLICATIONS

This application claims priority from U.S. Prov. Pat. App. No. 61/779,094 filed 13 Mar. 2013, which is entirely incorporated by reference herein for all purposes.

### BACKGROUND

Related fields include semiconductor fabrication, particularly thin-film structures based on germanium channels, bodies, layers or regions.

Traditional scaling of logic devices based on silicon (Si) has encountered challenges. Inherent material properties have become obstacles to further miniaturization, increased processing speed, and other fabrication and performance goals. For example, as gate conductor width decreases, gate dielectric thickness preferably also decreases, while still providing sufficient capacitance to control the transistor. Suppression of leakage current is a critical factor in capacitor dielectric performance. However, silicon oxide layers less than about 2 nm thick are subject to tunneling effects that result in unacceptably high leakage current.

Because tunneling leakage decreases as physical thickness increases, there has been exploration of gate dielectric materials that would yield capacitance values equivalent to 1-2 nm thick silicon dioxide (SiO₂) while being too physically thick (e.g., >=5 nm) to allow significant tunneling. Metal oxides with high dielectric constants (“high-k materials”) such as hafnium oxide (HfOₓ), aluminum oxide (Al₂O₃), and zirconium oxide (ZrOₓ) are among the materials being investigated as gate-dielectric candidates to replace silicon oxide.

Another avenue of exploration has been the replacement of Si channels with higher-mobility, lower-effective-mass materials such as germanium (Ge). Ge and Si—Ge are being explored for use as surface channels and strained buried channels. Indium gallium arsenide (InGaAs) is another Si substitute under consideration. The new materials, however, face various integration challenges. For example, Ge is susceptible, in the presence of virtually any oxygen source, to rapid growth of unstable native oxide. These oxides tend to increase operational power consumption and decrease reliability of the fabricated devices.

Uncontrolled native oxide growth under a capacitor dielectric can unpredictably affect the effective oxide thickness (EOT=(k_{SiO2}/k)t) and the capacitive effective thickness (CET^{˜}EOT+(k_{SiO2}/k)zavg for an ultra-thin gate dielectric) of a logic stack. In the equations, k=dielectric constant of the actual material, t=physical thickness of the actual material, zavg=average distance of inversion carriers from the gate-dielectric interface, and kSiO₂=dielectric constant of SiO₂^{˜}3.9.

Removing the native oxide from Ge immediately before forming an overlying layer has proven to be an incomplete solution. Although the ambient air that often triggers native GeOₓ growth is excluded from the ALD process chamber, the oxygen precursors (e.g., H₂O) used for the high-k layer deposition can encourage the native GeOₓ to regrow.

Sulfur passivation has shown some promise as a technique for inhibiting the regrowth. However, the exact passivation chemistry is not well understood, particularly its interactions with other unit processes such as the various approaches to native oxide removal. Therefore, a need exists for a rapid and effective way to select a set of formulas and process parameters for a GeOₓ removal—Ge passivation sequence.

### SUMMARY

The following summary presents some concepts in a simplified form as an introduction to the detailed description that follows. It does not necessarily identify key or critical elements and is not intended to reflect a scope of invention.

Embodiments of high-productivity combinatorial (HPC) screening methods use attenuated total reflectance Fourier transform infrared spectroscopy (ATR-FTIR), and optionally other measurements such as contact angle, atomic force microscopy (AFM), scanning electron microscopy (SEM), or X-ray fluorescence (XRF) to characterize Ge surfaces after candidate process sequences including oxide removal and subsequent surface passivation. A native oxide is allowed to form on a germanium substrate. Multiple site-isolated regions (SIR) are defined on the substrate, for example by the perimeters of individual processing reactors in a process tool. An area of the substrate within each SIR is subjected to a candidate process sequence including at least one of oxide removal or surface passivation. The process sequences for at least two of the SIRs differ from each other. The SIRs are characterized to determine the most successful process sequence (e.g., the least remaining or regrown native oxide).

Measuring an ATR-FTIR peak characteristic of germanium oxide (e.g., ^{˜}920 cm⁻¹) before, after or during the process and comparing the results reveals the extent of native oxide removal and, if present, later regrowth. Alternative indicators of native oxide presence, for example from re-growth, include contact angle, AFM/SEM imaging, and XRF. Candidate oxide removal processes may include, for example, exposure to hydrohalic mineral acid solutions containing 0.2-18 wt % hydrofluoric acid (HF), hydrochloric acid (HCl), or hydrobromic acid (HBr) for 15 seconds to 15 minutes at 20-30 C temperature in a nitrogen (N₂) ambient. Candidate passivation processes may include, for example, exposure to solutions containing sources of sulfur such as 0.1-25 wt % ammonium sulfide ((NH₄)₂S) for about 2-7 minutes at 25-80 C temperature.

Optionally, the substrate may be rinsed with de-ionized water or isopropyl alcohol for about 2-15 minutes at 20-25 C between oxide removal and surface passivation and/or at 25-80 C after passivation. Optionally, the substrate may be dried in N₂ ambient before or after passivation. Optionally, the substrate may be re-exposed to the oxide remover or the passivant sometime after the initial cleaning and/or passivation to measure any regrowth and the effect of the remover and/or passivant.

In an example set of experiments, HBr solutions removed the native germanium oxide (GeOₓ) more effectively than HF or HCl solutions. However, (NH₄)₂S passivation (which forms Ge—S surface bonds) prevented regrowth most effectively following an HF clean (rather than HCl or HBr), demonstrating the benefit of combinatorially screening process sequences as well as individual processes. While it is believed that HF hydrogenated the Ge surface (formed Ge—H bonds), HCl and HBr appeared to form Ge—Cl and Ge—Br bonds; the halogen, rather than the hydrogen, bonded to the surface. The Ge—Cl and Ge—Br surfaces appeared to resist native oxide regrowth more successfully than the Ge—S surfaces.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIG. 1 is a schematic diagram of device development using primary, secondary, and tertiary screening methods that include HPC processing and may also include conventional processing.

FIG. 2 is a simplified schematic diagram illustrating a general methodology for combinatorial process sequence integration that includes site-isolated processing, conventional processing, or both.

FIGS. 3A and 3B are two conceptual views of a combinatorially-processed substrate.

FIG. 4 is a schematic diagram of one type of generic combinatorial wet processing system used to investigate processes involving liquids.

FIGS. 5A-5D conceptually illustrate native oxide removal and passivation.

FIG. 6 is a flowchart of an example process for screening oxide removal and passivation processes and process sequences.

FIG. 7 is an example of a “split,” or matrix of combinatorial variations, for one stage of screening native-oxide removal and passivation processes.

FIG. 8 is a sample data graph of ATR-FTIR spectra of germanium oxides.

FIG. 9 is a sample data graph of germanium oxide peak height immediately after native oxide removal and after passivation.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

Unless the text or context clearly dictates otherwise: (1) By default, singular articles “a,” “an,” and “the” (or the absence of an article) may encompass plural variations; for example, “a layer” may mean “one or more layers.” (2) “Or” in a list of multiple items means that any, all, or any combination of less than all the items in the list may be used in the invention. (3) Where a range of values is provided, each intervening value is encompassed within the invention. (4) “About” or “approximately” contemplates up to 10% variation. “Substantially equal,” “substantially unchanged” and the like contemplate up to 5% variation.

“Horizontal” defines a plane parallel to the plane or surface of the substrate. “Vertical” shall mean a direction perpendicular to the horizontal. “Above,” “below,” “bottom,” “top,” “side” (e.g. sidewall), “higher,” “lower,” “upper,” “over,” and “under” are defined with respect to the horizontal plane. “On” indicates direct contact; “above” and “over” allow for intervening elements. “On” and “over” include conformal configurations covering feature walls oriented in any direction.

“Substrate,” as used herein, may mean any workpiece on which formation or treatment of material layers is desired. Substrates may include, without limitation, silicon, germanium, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter. Substrate surfaces may be treated before depositing, growing, or otherwise forming additional layers or features. Alternatively, an intended outer surface may be treated to confer desirable chemical or physical properties. “Surface,” as used herein, refers to a boundary between the environment and a feature of the substrate.

The term “passivating species” is used herein to refer to atomic or molecular species that are able to bind to dangling bonds on a semiconductor surface and discourage oxidation.

As used herein, “combinatorial processing” or “combinatorial variation” shall mean that a material or process parameter is caused to differ between at least two regions of a single substrate. Such parameters include, without limitation, process material amounts, reactant species, processing temperatures, processing times, processing pressures, processing flow rates, processing powers, processing reagent compositions, the rates at which the reactions are quenched, deposition order of process materials, process sequence steps, or hardware details. “Screening” shall mean “selecting one or more best-performing candidates from a larger evaluated group.”

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “site-isolated region” is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

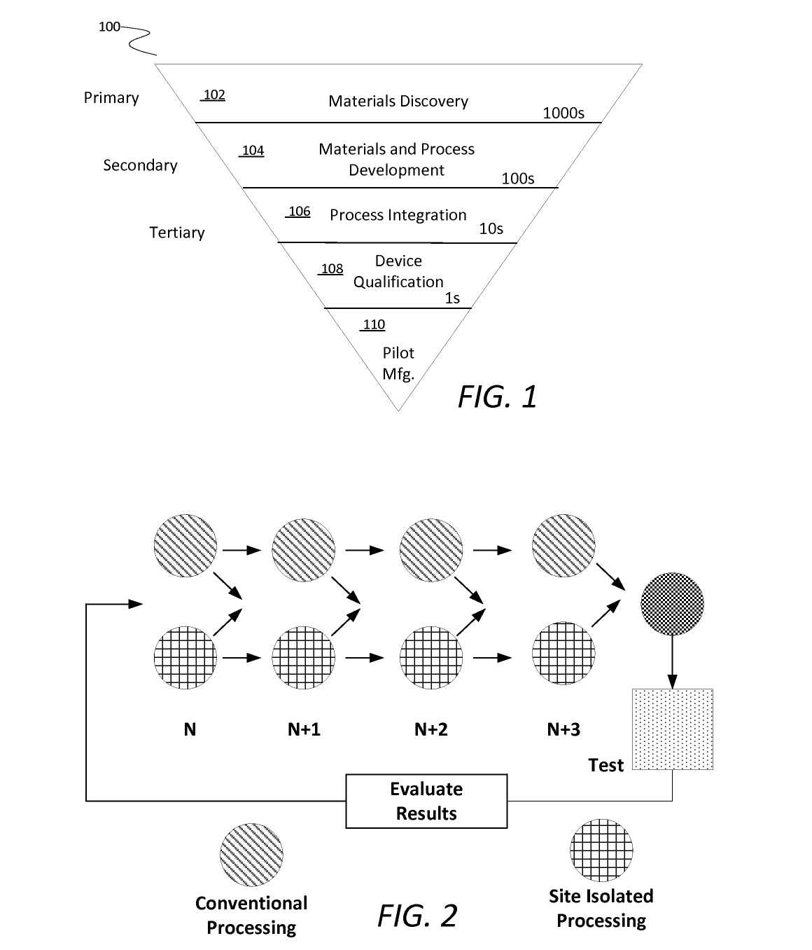

FIG. 1 is a schematic diagram of device development using primary, secondary, and tertiary screening methods that include HPC processing and may also include conventional processing. The diagram 100 illustrates how the selection of a subset of the most promising candidates at each stage decreases the relative number of combinatorial processes that need to be run in the next stage. Generally, a large number of processes are performed during a primary screening stage. Based on the primary-screening results, a subset of promising candidates is selected and subjected to a secondary screening stage. Based on the secondary-screening results, a smaller subset of promising candidates is selected and subjected to a tertiary screening stage, and so on. In addition, feedback from later stages to earlier stages can be used to refine the success criteria and provide better screening results.

For example, thousands of materials may be evaluated during a materials discovery stage 102, a primary screening stage. Techniques for this stage may include, e.g., dividing substrates into coupons and depositing materials on each of the coupons. Materials, deposition processes, or both may vary from coupon to coupon. The processed coupons are then evaluated using various metrology tools, such as electronic testers and imagers. A subset of promising candidates is advanced to the secondary screening stage, materials and process development stage 104.

Hundreds of materials (i.e., a magnitude smaller than the primary stage) may be evaluated during the materials and process development stage 104, which may focus on finding the best process for depositing each of the candidate materials. A subset of promising candidates is selected to advance to the tertiary screening stage, process integration stage 106.

Tens of material/process pairs may be evaluated during the process integration stage 106, which may focus on integrating the selected processes and materials with other processes and materials. A subset of promising candidates is selected to advance to device qualification stage 108.

A few candidate combinations may be evaluated during the device qualification stage 108, which may focus on the suitability of the candidate combinations for high volume manufacturing. These evaluations may or may not be carries out on full-size substrates and production tools. Successful candidate combinations proceed to pilot manufacturing stage 110.

The schematic diagram 100 is an example. The descriptions of the various stages are arbitrary. In other embodiments of HPC, the stages may overlap, occur out of sequence, or be described or performed in other ways.

HPC techniques may arrive at a globally optimal process sequence by considering the interactions between the unit manufacturing processes, the process conditions, the process hardware details, and material characteristics of components. Rather than only considering a series of local optima for each unit operation considered in isolation, these methods consider interaction effects between the multitude of processing operations, influenced by the order in which they are performed, to derive a global optimum sequence order.

HPC may alternatively analyze a subset of the overall process sequence used to manufacture a device; the combinatorial approach may optimize the materials, unit processes, hardware details, and process sequence used to build a specific portion of the device. Structures similar to parts of the subject device structures (e.g., electrodes, resistors, transistors, capacitors, waveguides, or reflectors) may be formed on the processed substrate as part of the evaluation.

While certain materials, unit processes, hardware details, or process sequences are varied, other parameters (e.g., composition or thickness of the layers or structures, or the unit process action such as cleaning, surface preparation, deposition, surface treatment, or the like) are kept substantially uniform across each discrete region of the substrate. Furthermore, while different materials or unit processes may be used for corresponding layers or steps in the formation of a structure in different regions of the substrate, the application of each layer or the use of a given unit process may be substantially consistent among the different regions. Thus, aspects of the processing may be uniform within a region (inter-region uniformity) or between regions (intra-region uniformity), as desired.

The result is a series of regions on the substrate that contain structures or unit process sequences that have been uniformly applied within that region or, as applicable, across different regions. This process uniformity allows comparison of the properties within and across the different regions so that the variations in test results are due to the intentionally varied parameter (e.g., material, unit process, unit process parameter, hardware detail, or process sequence) and not to a lack of process uniformity. The positions of the discrete regions can be defined as needed, but are preferably systematized for ease of tooling and design of experiments. The number, location, and variants of structures in each region preferably enable valid statistical analysis of test results within and between regions.

FIG. 2 is a simplified schematic diagram illustrating a general methodology for combinatorial process sequence integration that includes site-isolated processing, conventional processing, or both. In some embodiments, the substrate is initially processed using conventional process N, and then processed using site isolated process N+1. During site isolated processing, an HPC module may be used, such as the HPC module described in U.S. Pat. No. 8,084,400. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

Various other combinations of conventional and combinatorial processes can be included in the processing sequence. The combinatorial process sequence integration can be applied to any desired segments and/or portions of an overall process flow. Characterization can be performed after each process operation and/or series of process operations within the process flow as desired. Furthermore, the flows can be applied to entire monolithic substrates, or portions such as coupons.

Parameters which can be varied between site-isolated regions include, but are not limited to, process material amounts, reactant species, process temperatures, process times, process pressures, process flow rates, process powers, reagent compositions, the rates at which the reactions are quenched, atmospheres in which the processes are conducted, order in which materials are deposited, hardware details including gas or liquid distribution assemblies, etc. These process parameter examples are not an exhaustive list; numerous other process parameters used in device manufacturing may also be varied.

Within a region, the process conditions may be kept substantially uniform, in contrast to gradient processing techniques which rely on the inherent non-uniformity of the material deposition. That is, each site-isolated region may be processed in a substantially consistent and substantially uniform way, even though the materials, processes, and process sequences may vary from region to region over the substrate. Thus, the testing will find optima without interference from process variation differences between processes that are meant to be the same. Regions may be contiguous, or may overlap, or may be surrounded by unprocessed margins. Where regions are contiguous or overlapping, the materials or process interactions in the overlap may be uncertain. However in some embodiments at least 50% of the area within a region is uniformly processed and all testing can be done in that uniform area. Experiments may be designed to allow potential overlap only between materials or processes that will not adversely affect the result of the tests.

Combinatorial processing can be used to determine optimal processing parameters (e.g., time, concentration, temperature, stirring rate, etc.) of wet processing techniques such as wet etching, wet cleaning, rinsing, and wet deposition techniques (e.g., electroplating, electroless deposition, chemical bath deposition, dip coating, spin coating, and the like).

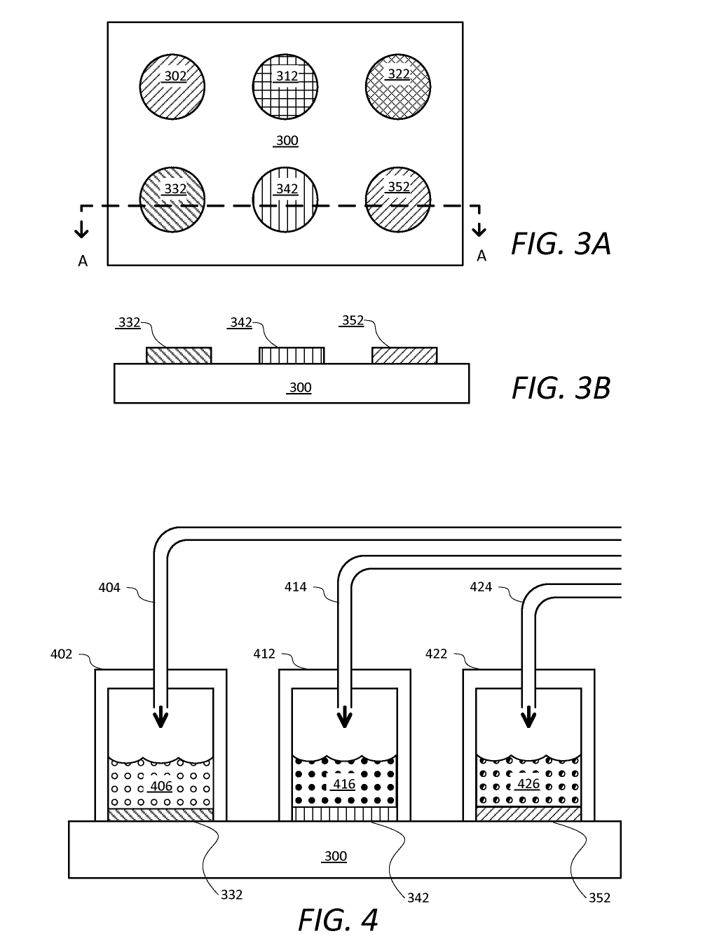

FIGS. 3A and 3B are two conceptual views of a combinatorially-processed substrate. FIG. 3A is a top view of substrate 301 showing 6 site-isolated regions 302, 312, 322, 332, 342, and 352. Although substrate 301 is rectangular in the illustration, any suitable substrate shape such as circular, square, or polygonal may also be used in some embodiments. Although the site-isolated regions 302, 312, 322, 332, 342, and 352 are shown as separated from each other by unprocessed areas of substrate 301, in some embodiments the site-isolated regions may be contiguous or partially overlapping. Some of the site-isolated regions may be chosen to be processed identically (as regions 302 and 352 are shown here with identical shading) to test the consistency of the results on different regions of the same substrate.

FIG. 3B is a sectional view through section line A-A of FIG. 3A showing different films formed on site-isolated regions 332, 342, and 352. The regions could alternatively have identical (or no) films formed, and the variation could instead be in the cleaning, etching, polishing, or some other treatment of the different regions.

FIG. 4 is a schematic diagram of one type of generic combinatorial wet processing system used to investigate processes involving liquids. Substrate 300 and site-isolated regions 332, 342, and 352 are shown in cross-section similarly to FIG. 3B. Each site-isolated region is covered by one of the individual reactor cells 402, 412, and 422. The reactor cells confine different liquids 406, 416, and 426 to their main cavities 401, 411, and 421 and thus to the underlying regions 332, 342, and 352 of the substrate. Conduits 404, 414, and 424 are connected to the cells. Some types of conduits deliver process liquid to the reactor cells, while other conduits may remove the process liquids, inject or remove gases or buffer liquids, or maintain pressure equilibrium with the chamber ambient. The illustrated conduits 404, 414, and 424 are in fluid communication with main cavities 401, 411, and 421 of reactor cells 402, 412, and 422 through ports 405, 415, and 425 respectively. Wet processes such as cleaning, etching, surface treatment, surface functionalization, etc. may be investigated by HPC by varying liquid parameters (e.g., composition, temperature, exposure time) between different site-isolated regions.

This type of apparatus could be used, for example, to expose different SIRs on a substrate to different native-oxide removal solutions, rinses, passivation solutions, additional rinses, and drying conditions.

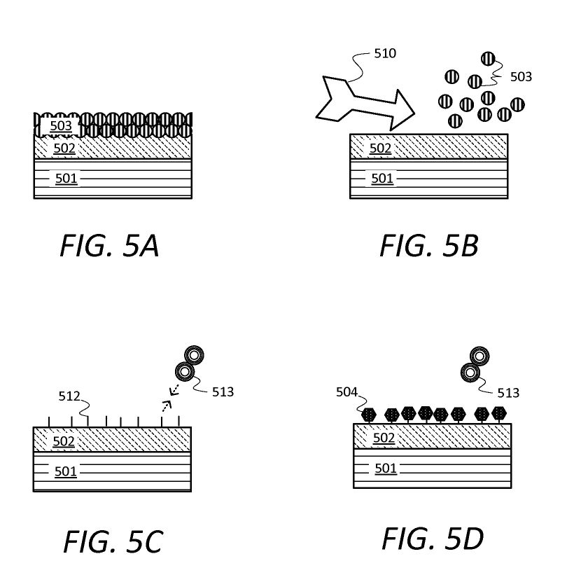

FIGS. 5A-5D conceptually illustrate native oxide removal and passivation. In FIG. 5A, substrate 501 has a top semiconductor layer 502. Substrate 501 may have any number of other layers under top semiconductor layer 502, or alternatively semiconductor layer 502 may be the bulk material of the substrate. Top semiconductor layer 502 has a native oxide 503 on its upper surface. Such native oxides 503 routinely grow on semiconductors such as silicon, germanium, or InGaAs when the semiconductors are exposed to the oxygen in ambient air, but they can also result from exposure to other sources of oxygen such as deionized rinse water or neighboring oxide layers.

In FIG. 5B, a removal process 510 removes native oxide 503 from the top surface of semiconductor 502. A number of processes for this removal are known in the art, such as wet etches, polishing, laser ablation, plasma treatments, and others. Typically, the native oxide is removed because another structure needs to be formed in direct contact with the semiconductor, or, in some materials such as Ge and III-V materials, the native oxide is unstable and non-self-limiting and adds an unpredictable and inconsistent factor to the devices as well as an insulating layer.

In FIG. 5C, semiconductor layer 502 is free of native oxide but has unsatisfied or “dangling” bonds 512 on its surface. These empty bonding sites can attract more oxygen 513 to regrow the native oxide 503. Surface damage can cause lattice defects in which additional bonds are broken. Thus, the method of removing the native oxide can affect the density of unsatisfied bonds 512. “Mild” treatments may leave fewer unsatisfied bonds (and, in some cases, remove less of the underlying semiconductor), but may remove the oxide more slowly or less thoroughly. “Aggressive” treatments work quickly and efficiently but may leave more surface damage that adds to the number of unsatisfied bonds (and, in some cases, remove more of the underlying semiconductor along with the oxide).

In FIG. 5D, a passivant 504 has been applied to satisfy the dangling bonds 512, leaving few or no empty sites for oxygen 513 to bond and regrow the native oxide. A number of different chemicals, such as hydrogen, halogens, and sulfur, may operate as passivants for different semiconductors.

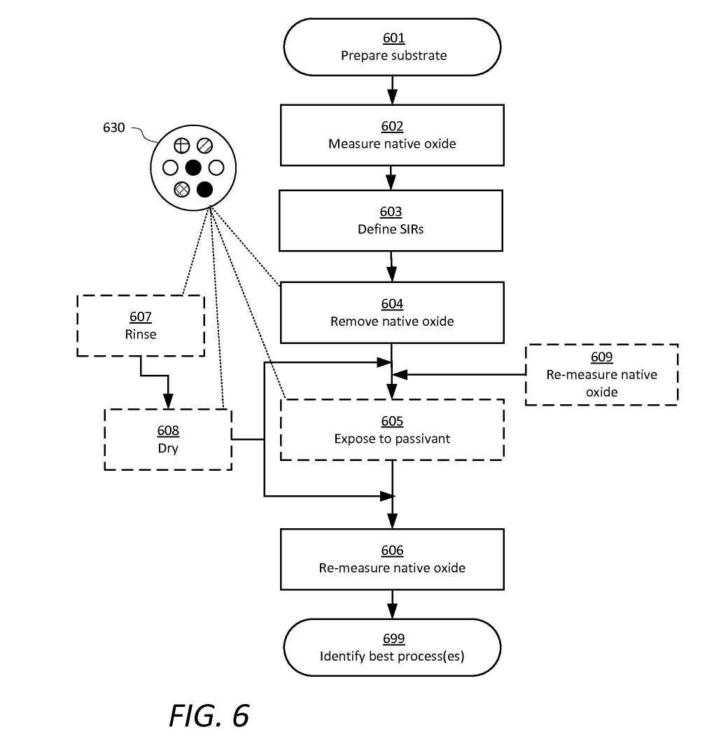

FIG. 6 is a flowchart of an example process for screening oxide removal and passivation processes and process sequences. Step 601 of preparing the substrate may include cleaning, degassing, and formation of the semiconductor (e.g., Ge) layer if it is not already present. Step 602 of initially measuring the native oxide (e.g., by ATR-FTIR, contact angle, AFM/SEM imaging, or XRF) provides a baseline for comparison with measurements made after processing. Step 603 of defining SIRs on the substrate may include, for example, engaging an individual wet reactor (such as discussed with reference to FIG. 4) with each of the regions. Step 604 of removing native oxide from one or more of the SIRs may include, for example, exposure to a hydrohalic mineral acid solution containing 0.2-18 wt % hydrofluoric acid (HF), hydrochloric acid (HCl), or hydrobromic acid (HBr) for 15 seconds to 15 minutes at 20-30 C temperature in a nitrogen (N₂) ambient.

Optional step 605 of exposing the semiconductor surfaces of one or more of the SIRs to a passivant may include, for example, exposure to a sulfur passivant such as a solution of 20-25 wt % ammonium sulfide ((NH₄)₂S) for about 2-7 minutes at a temperature between 25 C and 80 C. Passivation 605 may be preceded by optional step 609 of re-measuring the native oxide to measure the effect of the removal alone without the passivant. Optional step 607 of rinsing (e.g., with de-ionized water or isopropyl alcohol for about 5-15 minutes), with or without optional step 608 of drying (e.g., in a nitrogen ambient), may be interposed either after native oxide removal 604 or after passivation 605.

Combinatorial variation 630 may be applied to any one or more of native oxide removal 604, passivation 605, rinsing 607, and drying 608. Step 606 of re-measuring the native oxide (e.g., by ATR-FTIR, contact angle, AFM/SEM imaging, or XRF) provides a comparison of the results of the different processes performed on the different SIRs. Optionally, re-measuring 606 may be done at multiple times after processing to measure a regrowth rate of native oxide. Step 699 of identifying the best process(es) may include, for example, identifying the process corresponding to the SIR with the least native oxide regrowth. These best processes may be advanced to a next screening stage.

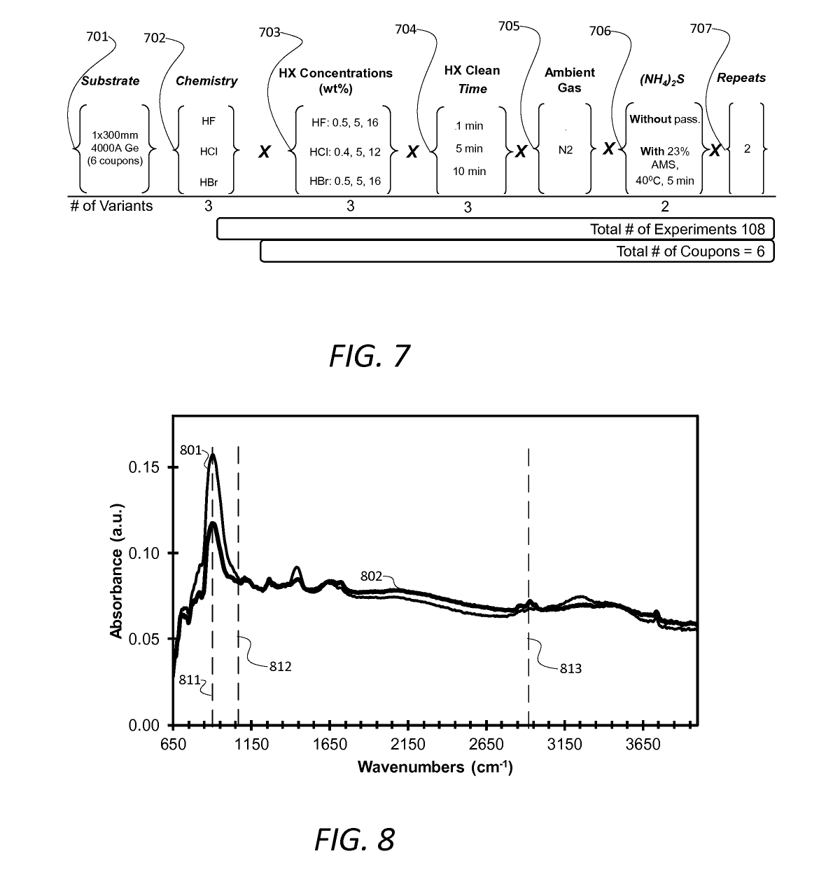

FIG. 7 is an example of a “split,” or matrix of combinatorial variations, for one stage of screening native-oxide removal and passivation processes. In this non-limiting example, the substrate type 701 is not varied. Three different hydrohalic acids 702 are compared for removing the native oxide. Each of the acids 702 is tested at three different concentrations 703. Each of the concentrations is tested at three different exposure times 704. The ambient gas 705 is nitrogen for all the tests. The passivation 706 is either not done, or done with 23 wt % ammonium sulfide at 40 C for 5 minutes. Each of the sets of process conditions is run for 2 repeats 707. 108 screening experiments are thus performed using only 6 substrates (coupons) by defining 18 SIRs on each coupon.

FIG. 8 is a sample data graph of ATR-FTIR spectra of germanium oxides. This example compares a thicker oxide (curve 801, thinner line) with a thinner oxide (curve 802, thicker line). A baseline value at ^{˜}1076 cm⁻¹ (position 812) is subtracted from the Ge—O bond's peak height at ^{˜}920 cm⁻¹ (position 811) to measure the amount of GeOₓ on the substrate. The measurements may be compared between different SIRs and/or before vs. after processing.

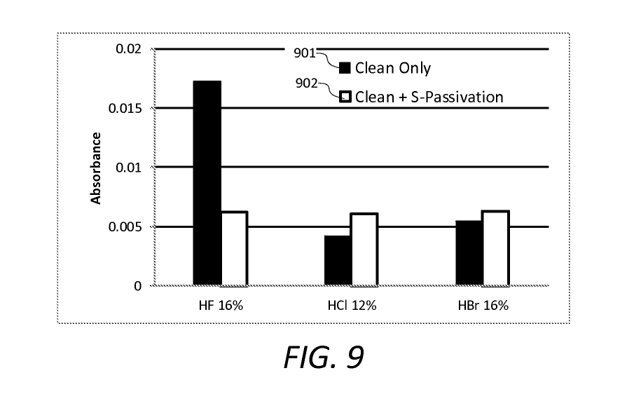

FIG. 9 is a sample data graph of germanium oxide peak height immediately after native oxide removal and after passivation. All the samples were treated with their respective hydrohalic acids at 25 C for 10 minutes, rinsed with isopropyl alcohol or deionized water at 25 C, passivated with 23 wt % ammonium sulfide at 40 C for 10 minutes, rinsed with isopropyl alcohol or deionized water at 40 C for 1 minute, and dried with nitrogen gas at 40 C.

The black bars 901 represent measurements taken directly after native oxide removal (e.g., step 604 in FIG. 6). The most re-growth occurred after the 16 wt % HF native-oxide removal. Without being bound by any particular theory, it is believed that the HF reaction may break Ge—Ge bonds, forming more dangling bonds (e.g., unsatisfied bonds 512 in FIG. 5) to bond with available oxygen and re-grow native GeOₓ. Other research has suggested that the HF mainly forms Ge—H bonds on the Ge surface, but HCl mainly forms Ge—Cl bonds and HBr mainly forms Ge—Br bonds.

The white bars 902 represent measurements taken after passivation (e.g., step 606 in FIG. 6). The re-growth after HBr was much less than HF, and the re-growth after HCl was somewhat less than HCl. Interestingly, the ammonium sulfide passivation caused the same amount of re-growth in all three samples. Although the passivation step significantly reduced the regrowth in the HF sample, the HCl and HBr samples actually had more re-growth with passivation than without passivation. Without being bound by any particular theory, it is believed that the HCl and HBr solutions more effectively passivate the Ge than HF or any of the combinations with the extra ammonium sulfide step. This suggests that a process using HCl or HBr at room temperature (^{˜}20-30 C) might be able to skip the sulfur passivation step and the attendant heating of the substrate, while still producing an equivalent or better Ge surface than a process with sulfur passivation.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method, comprising:
providing a substrate having a native oxide layer over a semiconductor surface;
defining a plurality of site-isolated regions on the substrate;
removing the native oxide layer from the semiconductor surface using different processes for at least two of the site-isolated regions;
measuring an indicator of the presence native oxide in the site-isolated regions;
comparing measurements of the indicator for the site-isolated regions subjected to the different processes; and
screening the processes based on the comparing.

2. The method of claim 1, wherein the substrate comprises germanium.

3. The method of claim 1, wherein the removing of the native oxide comprises exposure to a solution comprising a hydrohalic mineral acid.

4. The method of claim 3, wherein the solution comprises a hydrohalic acid.

5. The method of claim 3, wherein a weight percentage of the hydrohalic acid in the solution is between about 0.2 wt % and about 18 wt %.

6. The method of claim 1, wherein the removing of the native oxide is performed at a temperature between about 20 C and about 30 C.

7. The method of claim 1, wherein the removing of the native oxide is performed for a duration between about 15 seconds and about 15 minutes.

8. The method of claim 1, wherein the removing of the native oxide is performed in a nitrogen ambient.

9. The method of claim 1, wherein the measuring an indicator of native oxide comprises one of attenuated total reflectance Fourier transform infrared spectroscopy, contact angle, atomic force microscopy, scanning electron microscopy, or X-ray fluorescence.

10. The method of claim 1, further comprising passivating the surface with an ammonium sulfide solution after the removing of the native oxide.

11. The method of claim 10, wherein a weight percentage of ammonium sulfide in the ammonium sulfide solution is between about 20 wt % and about 25 wt %.

12. The method of claim 10, wherein the passivation is performed for a duration between about 2 minutes and about 7 minutes.

13. The method of claim 10, wherein the passivation is performed at a temperature between about 35 C and about 45 C.

14. The method of claim 10, further comprising rinsing the surface between the removing of the native oxide and the passivating.

15. The method of claim 14, wherein the rinsing comprises exposure to isopropyl alcohol or de-ionized water.

16. The method of claim 14, wherein the rinsing is performed for a duration between about 5 minutes and about 15 minutes.

17. The method of claim 10, further comprising rinsing the surface at a temperature between about 20 C and about 45 C after the passivating.

18. The method of claim 10, further comprising drying the surface in a nitrogen ambient.

19. A method, comprising:
exposing a native oxide layer on a germanium surface to an acid solution; and
rinsing the germanium surface with a solution comprising de-ionized water or isopropyl alcohol;
wherein the acid solution comprises between about 10 wt % and 18 wt % of hydrochloric acid or hydrobromic acid; and
wherein the exposing and the rinsing are performed at a temperature between about 20 C and about 30 C.

20. A method, comprising:
exposing a native oxide layer on a germanium surface to an acid solution;
rinsing the germanium surface with a solution comprising de-ionized water or isopropyl alcohol; and
passivating the germanium surface in an ammonium sulfide solution;
wherein the acid solution comprises between about 10 wt % and 18 wt % of hydrofluoric acid;
wherein the exposing and the rinsing are performed at a temperature between about 20 C and about 25 C; and
wherein the passivating is performed at a temperature between about 35 C and about 45 C.
